(19) United States
(12) Patent Application Publication
(10) Pub. No.: US 2006/0209512 A1
(43) Pub. Date: Sep. 21, 2006

(54) Heat receiving member, heat receiving device and electronic equipment

(75) Inventors: Jun Taniguchi, Kawasaki (JP); Hideshi Tokuhira, Kawasaki (JP); Minoru Ishinabe, Kawasaki (JP); Masatomo Asano, Kawasaki (JP); Nobuhiro Nanri, Kawasaki (JP)

Correspondence Address: ARENT FOX PLLC, 1050 CONNECTICUT AVENUE, N.W., SUITE 400, WASHINGTON, DC, 20036, US

(73) Assignee: Fujitsu Limited

(21) Appl. No.: 11/165,118

(22) Filed: Jun. 24, 2005

(30) Foreign Application Priority Data
Mar. 17, 2005 (JP) 2005-078118

(51) Int. Cl. H05K 7/20; F28F 7/00

(52) U.S. Cl. 361/699; 165/80.4

(57) ABSTRACT

A heat receiving member of a heat receiving device includes a coolant passage comprising a bag formed of a flexible sheet made up of a thermally stable, flexible plastic material and a metal film having high heat conductivity. In the coolant passage flows a coolant having an anti-corrosion property. A heat generating member including a main body and a terminal portion is supported by an adapter fitted in an opening formed in the flexible sheet. The main body of the heat generating member comes into direct contact with the coolant flowing in the coolant passage. Since the heat from the heat generating member is directly transferred to the coolant, the heat transfer path between the heat generating member and the coolant becomes shorter. Therefore, the heat resistance is reduced, so that the heat receiving efficiency is extremely high.

### CROSS-REFERENCE TO RELATED APPLICATION

This Nonprovisional application claims priority under 35U.S.C.§119(a) on Patent Application No. 2005-78118 filed in Japan on Mar. 17, 2005, the entire contents of which are hereby incorporated by reference.

### BACKGROUND OF THE INVENTION

The present invention relates to a heat receiving member for receiving heat from a heat generating member such as an electronic component mounted in an electronic equipment by a coolant flowing in a coolant passage. The invention also relates to a heat receiving device including a heat generating member and a heat receiving member, and an electronic equipment in which a heat generating member is mounted on a printed circuit board.

An electronic equipment such as a desktop computer, a notebook type computer or mobile communication device includes a plurality of electronic components such as a CPU device, a coil element or a capacitor mounted on a printed circuit board. Recently, as the processing speed, function and performance of such electronic equipment are enhanced, the amount of heat generated during the operation of the electronic components tends to increase. To maintain the stable operation of the electronic equipment, the heat generated from the electronic components need be quickly dissipated to the outside for enhancing the heat dissipation performance.

Generally, for this purpose, such electronic equipment is provided with an air-cooling-type cooling device for cooling the electronic components. Such a cooling device includes a heat sink for absorbing heat from the electronic components and dissipating the heat, and a cooling fan for supplying cooling wind to the heat sink. Since it is expected that the amount of heat generation in electronic equipment continues to increase as described above, improvement of such a cooling device is desired.

To enhance the cooling performance of such an air-cooling-type cooling device, measures are taken such as increasing the size of the heat sink or enhancing the performance of the cooling fan, for example. However, when a large heat sink is used, the size of electronic equipment for incorporating the heat sink is inevitably increased. On the other hand, to enhance the performance of the cooling fan, the size of the fan structure or the number of revolutions of the cooling fan need be increased. However, when such a measure is taken, an increase in the size of the electronic equipment or in the fan noise is inevitable. Particularly, for a notebook type computer, in addition to the cooling performance, the portability, i.e. the size and weight of the equipment and the silence, i.e. making little noise during the operation are also important requirements, and the above-described measures to enhance the cooling performance are not incompatible with such requirements.

To solve the above problems, a liquid-cooling-type cooling system has been proposed which utilizes, as the coolant, liquid whose specific heat is considerably higher than that of the air. (For example, Japanese Patent Application Laid-Open No. 2001-237582, Japanese Patent Application Publication No. 7-9956 (1995) and Japanese Patent Application Laid-Open No. 4-276699 (1992), for example.)

In the cooling device of electronic equipment (notebook type computer) disclosed in Japanese Patent Application Laid-Open No. 2001-237582, a heat receiving portion for coming into contact with a heat generating member (electronic component), a heat dissipation portion and a pump are connected to each other via a pipe, and a liquid coolant is circulated in the pipe to transfer the heat from the heat generating member to the heat dissipation portion. The structural parts except the pump are in the form of a bag made of a flexible material to reduce the thickness and weight of the device.

FIG. 1 shows the heat receiving structure of the prior art (Japanese Patent Application Laid-Open No. 2001-237582). A coolant passage 2 in the form of a bag made of a flexible sheet 11 is arranged in contact with the heat generating member 1, and a liquid coolant 3 flows in the coolant passage 2. In this prior art structure, since the flexible sheet 11 intervenes between the heat generating member 1 and the coolant 3, the heat resistance is high. Therefore, the heat from the heat generating member 1 cannot be received efficiently.

### BRIEF SUMMARY OF THE INVENTION

An object of the present invention, which is conceived under such circumstances, is to provide a heat receiving member which is capable of efficiently receiving heat from a heat generating member by bringing the heat generating member into direct contact with a coolant, to provide a heat receiving device including such a heat generating member and a heat receiving member, and to provide an electronic equipment including a printed circuit board on which a heat generating member is mounted.

A heat receiving member according to the present invention includes a coolant passage for flowing a coolant for receiving heat generated at a heat generating member. The heat receiving member is formed with an opening for fitting the heat generating member so that the heat generating member comes into contact with the coolant. In the heat receiving member of the present invention, the heat generating member comes into contact with the coolant in the coolant passage. Therefore, an obverse surface of the heat generating member comes into direct contact with the coolant. As a result, the heat transfer path between the heat generating member and the coolant becomes shorter, and hence, the heat resistance is reduced, so that the heat receiving efficiency is enhanced.

In the heat receiving member according to the present invention, the coolant comprises a liquid having an anti-corrosion property. Since a liquid having an anti-corrosion property is used as the coolant in the heat receiving member of the present invention, the heat generating member does not corrode even in direct contact with the coolant.

A heat receiving device according to the present invention comprises a heat generating member at which heat is generated, and a heat receiving member including a coolant passage for flowing a coolant for receiving heat from the heat generating member. The heat receiving member is formed with an opening, and the heat generating member is fitted in the opening to come into contact with the coolant. In the heat receiving device of the present invention, the heat generating member fitted in the opening of the heat receiving member comes into direct contact with the coolant. Therefore, the heat transfer path between the heat generating member and the coolant becomes shorter, and hence, the heat resistance is reduced, so that the heat receiving efficiency is enhanced.

In the heat receiving device according to the present invention, the heat generating member includes a main body and a terminal portion, and the main body of the heat generating member comes into contact with the coolant. In the heat receiving device of the present invention, since the main body of the heat generating member comes into contact with the coolant, problems such as electrical short-circuiting and deterioration of the property of the terminal portion do not occur.

An electronic equipment according to the present invention comprises a heat receiving member including a coolant passage for flowing a coolant for receiving heat generated at a heat generating member, and a printed circuit board on which the heat generating member is mounted. The heat receiving member is formed with an opening, and the heat generating member is fitted in the opening to come into contact with the coolant. In the electronic equipment of the present invention, the heat generating member such as an electronic component mounted on the printed circuit board is fitted into the opening of the heat receiving member to come into direct contact with the coolant. Therefore, the heat transfer path between the heat generating member and the coolant becomes shorter, and hence, the heat resistance is reduced, so that the heat receiving efficiency is enhanced.

The above and further objects and features of the invention will more fully be apparent from the following detailed description with accompanying drawings.

### BRIEF DESCRIPTION OF THE SEVERAL VIEWS OF THE DRAWINGS

FIG. 1 shows a prior art heat receiving structure;

FIG. 2 is a perspective view showing an electronic equipment to which the present invention is applied;

FIG. 3 is a sectional view showing a heat receiving device according to a first embodiment; and

FIG. 4 is a sectional view showing a heat receiving device according to a second embodiment.

### DETAILED DESCRIPTION OF THE INVENTION

The present invention will be described below in detail with reference to the drawings showing the embodiments. It is to be noted that the present invention is not limited to the following embodiments.

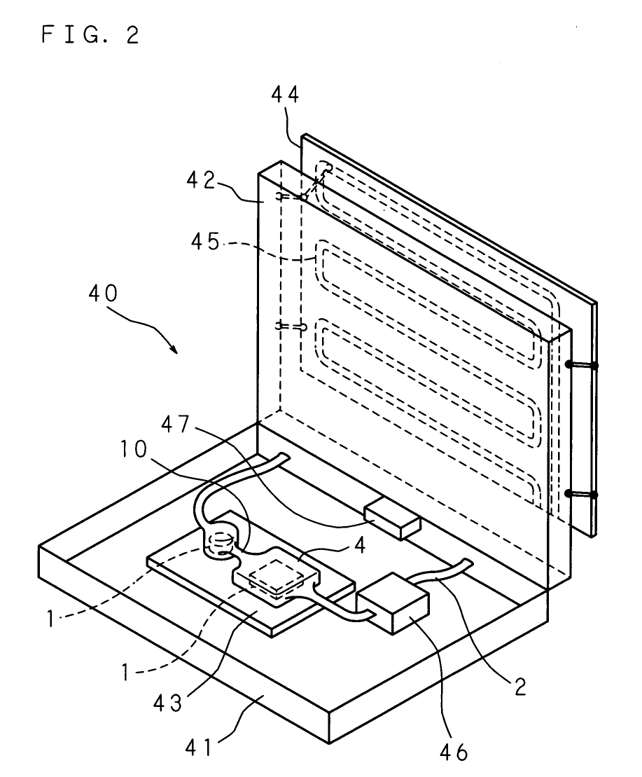

FIG. 2 is a perspective view showing an electronic equipment to which the present invention is applied. The electronic equipment 40 may be e.g. a notebook type computer and includes a first housing 41 on the main unit side and a second housing 42 on the display side. In the first housing 41, a printed circuit board 43 is disposed on which one or a plurality of electronic components (such as a CPU device or a coil element) as a heat generating member 1 are mounted. Above the heat generating member 1, a heat receiving member 4 is provided which includes a coolant passage 2 comprising a bag made of a flexible sheet. In the coolant passage 2, a liquid coolant having an anti-corrosion property flows. The heat generating member 1 and the heat receiving member 4 constitute a heat receiving device 10 according to the present invention. The structure of the heat receiving device 10 will be described in detail in each of the following embodiments.

The coolant passage 2 communicates with a coolant passage 45 formed in a heat dissipation plate 44 attached to the second housing 42 as a heat dissipation portion. A pump 46 is provided at some midpoint of the coolant passage 2 so that the liquid coolant circulates within the coolant passage 2 and the coolant passage 45 by driving the pump 46. Further, in the first housing 41, a fan 47 is provided to supply cooling air between the second housing 42 and the heat dissipation plate 44.

The heat dissipation process will be described below. During the heat dissipation process, the heat dissipation plate 44 is kept open. The heat generated at the heat generating member 1 is transferred to the liquid coolant flowing through the coolant passage 2, and the coolant flows through the coolant passage 45 to dissipate the heat to the outside through the heat dissipation plate 44. During this process, the heat dissipation effect is promoted by supplying, from the fan 47, cooling air between the second housing 42 and the heat dissipation plate 44.

The structure of the heat receiving device 10 as the characteristic portion of the present invention will be described below in detail.

### First Embodiment

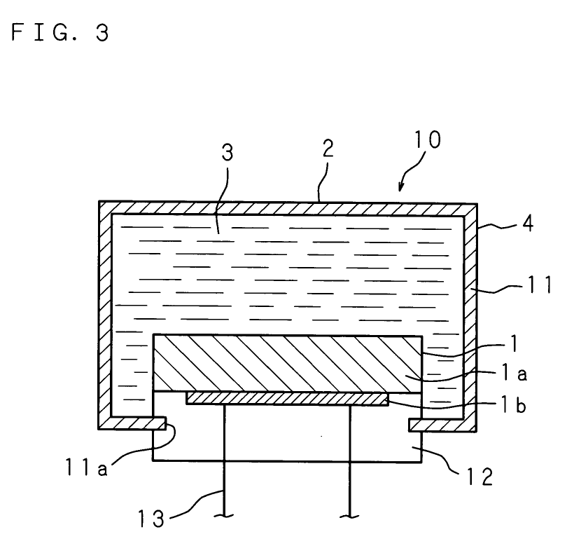

FIG. 3 is a sectional view of a heat receiving device 10 according to a first embodiment of the present invention. The coolant passage 2 of the heat receiving member 4 comprises a bag formed of a flexible sheet 11 made up of a thermally stable, flexible plastic material and a metal film having high heat conductivity. In the coolant passage 2 flows a coolant 3 having an anti-corrosion property, such as propylene glycol-based aqueous solution which is a coolant used for a car heat exchanger, for example. The flexible sheet 11 is formed with an opening 11a.

The heat generating member 1, which is an electronic component, includes a main body 1a and a terminal portion 1b and is supported by an adapter 12 fitted in the opening 11a of the flexible sheet 11. The adapter 12 is provided with a wiring 13 for connecting an electrode of the terminal portion 1b of the heat generating member 1 to an external terminal. The main body 1a of the heat generating member 1 is brought into direct contact with the coolant 3 in the coolant passage 2, whereas the terminal portion 1b is not brought into contact with the coolant 3. Part of the flexible sheet 11 is embedded into the adapter 12 for providing high airtightness, so that the coolant 3 in the coolant passage 2 does not leak to the outside.

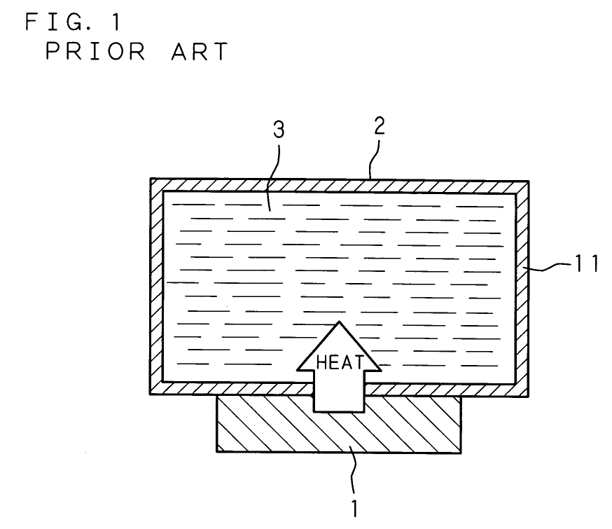

The main body 1a of the heat generating member 1 comes into direct contact with the coolant 3 flowing in the coolant passage 2. Therefore, unlike the prior art structure (FIG. 1) in which the flexible sheet 11 intervenes between the heat generating member 1 and the coolant 3, the heat from the heat generating member 1 is directly transferred to the coolant 3. Therefore, the heat transfer path between the heat generating member 1 and the coolant 3 becomes shorter, and hence, the heat resistance is reduced, so that the heat receiving efficiency is extremely high.

Since the heat generating member 1 which is an electronic component comes into direct contact with the coolant 3, there may be a concern that the property of the heat generating member 1 may be deteriorated. However, since an anti-corrosion coolant such as propylene glycol-based aqueous solution is used, the heat generating member 1 is not corroded by the coolant 3, so that deterioration of the property does not occur. Further, since the terminal portion 1b of the heat generating member 1 does not come into contact with the coolant 3, the property of the terminal portion 1b is not deteriorated.

In some kind of heat generating member 1, a metal pad may be provided as exposed at an obverse surface which comes into contact with the coolant 3. In the case of such a heat generating member 1, it is preferable to cover the metal pad with resin before the heat generating member 1 is brought into contact with the coolant 3.

### Second Embodiment

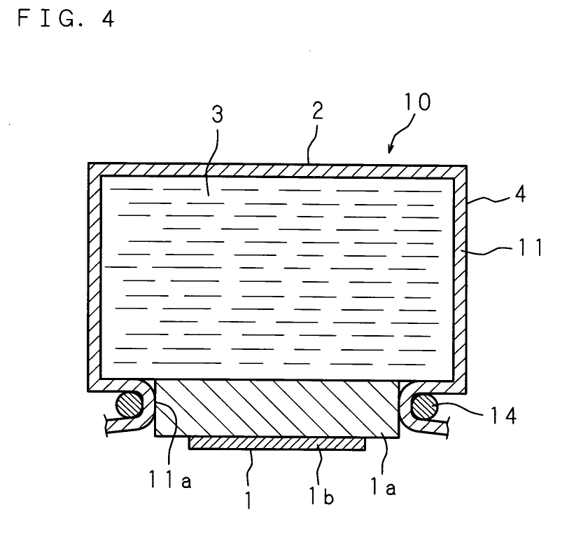

FIG. 4 is a sectional view showing a heat receiving device 10 according to a second embodiment of the present invention. The coolant passage 2 comprises a bag made of a flexible sheet 11. In the coolant passage 2 flows a coolant having an anti-corrosion property (e.g. propylene glycol-based aqueous solution). The flexible sheet 11 is formed with an opening 11a, and the heat generating member 1 is fitted in the opening 11a. Part of the flexible sheet 11 is fixed to the sides of the heat generating member 1 by a leak preventing rubber member 14 arranged outside the flexible sheet 11, and the opening 11a is hermetically sealed by the heat generating member 1. Therefore, the coolant 3 does not flow outside the coolant passage 2 through the opening 11a.

The obverse surface of the main body 1a of the heat generating member 1 comes into direct contact with the anti-corrosion coolant 3 flowing in the coolant passage 2. Therefore, similarly to the first embodiment, the heat resistance can be reduced and the heat receiving efficiency can be considerably enhanced without deteriorating the property of the terminal portion 1b of the heating generating element 1.

In the above-described examples, propylene glycol-based aqueous solution is used as the coolant to flow in the coolant passage 2. However, other kinds of coolant, such as an acetic acid-based coolant, for example, may be used as long as it has an anti-corrosion property.

As described above, in the present invention, the heat generating member is fitted into the opening of the heat receiving member including the coolant passage so that the heat generating member comes into direct contact with the coolant. Therefore, the heat transfer path between the heat generating member and the coolant can be shortened to reduce the heat resistance, so that the heat receiving efficiency can be enhanced.

Further, in the present invention, a liquid having an anti-corrosion property is used as the coolant. Therefore, the heat generating member does not corrode even when it is brought into direct contact with the coolant. In this way, adverse effect by the coolant on the heat generating member can be prevented.

Moreover, in the present invention, the main body of the heat generating member is brought into contact with the coolant. Therefore, the direct contact of the heat generating member with the coolant does not cause problems such as electrical short-circuiting or deterioration of the property of the terminal portion.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1. A heat receiving member including a coolant passage for flowing a coolant for receiving heat generated at a heat generating member;
wherein the heat receiving member is formed with an opening for fitting the heat generating member so that the heat generating member comes into contact with the coolant.

2. The heat receiving member according to claim 1, wherein the coolant passage comprises a bag made of a flexible sheet.

3. The heat receiving member according to claim 1, wherein the coolant comprises a liquid having an anti-corrosion property.

4. The heat receiving member according to claim 3, wherein the coolant passage comprises a bag made of a flexible sheet.

5. A heat receiving device comprising:
a heat generating member at which heat is generated; and
a heat receiving member including a coolant passage for flowing a coolant for receiving heat from the heat generating member;
wherein the heat receiving member is formed with an opening, and the heat generating member is fitted in the opening to come into contact with the coolant.

6. The heat receiving device according to claim 5, wherein the coolant passage comprises a bag made of a flexible sheet.

7. The heat receiving device according to claim 5, wherein the heat generating member includes a main body and a terminal portion, and the main body of the heat generating member comes into contact with the coolant.

8. The heat receiving device according to claim 7, wherein the coolant passage comprises a bag made of a flexible sheet.

9. An electronic equipment comprising:
a heat receiving member including a coolant passage for flowing a coolant for receiving heat generated at a heat generating member; and
a printed circuit board on which the heat generating member at which heat is generated is mounted;
wherein the heat receiving member is formed with an opening, and the heat generating member is fitted in the opening to come into contact with the coolant.

10. The electronic equipment according to claim 9, wherein the coolant passage comprises a bag made of a flexible sheet.
